(19) United States
(12) Patent Application Publication
(10) Pub. No.: US 2026/0282453 A1
(43) Pub. Date: Sep. 17, 2026

(54) LAMINATE FOR MANUFACTURING FLEXIBLE TRANSPARENT THIN-FILM TRANSISTOR, AND FLEXIBLE TRANSPARENT THIN-FILM TRANSISTOR AND MANUFACTURING METHOD THEREOF

(71) Applicant: DONGWOO FINE-CHEM CO., LTD., Iksan-si (KR)

(72) Inventors: Myeong-Won LEE, Iksan-si (KR); Jin LEE, Iksan-si (KR); Jin-Koo LEE, Iksan-si (KR)

(73) Assignee: DONGWOO FINE-CHEM CO., LTD., Iksan-si (KR)

(21) Appl. No.: 19/168,101

(22) PCT Filed: Feb. 27, 2024
(86) PCT No.: PCT/KR2024/002468

§ 371 Date: Sep. 23, 2025

(30) Foreign Application Priority Data
Mar. 27, 2023 (KR) 10-2023-0039873

(51) Int. Cl. H10D 30/67; H10D 30/01

(52) U.S. Cl. CPC H10D 30/6755; H10D 30/0316; H10D 30/6704; H10D 30/675; H10D 30/6757; H10D 30/6758; H10D 30/6732

(57) ABSTRACT

The present invention relates to a laminate for manufacturing a flexible thin-film transistor, and a flexible thin-film transistor manufactured using same and a manufacturing method thereof, the laminate comprising: a carrier substrate; an isolation layer provided on the carrier substrate; a protective layer provided to cover the isolation layer; a gate electrode provided on the protective layer; a gate insulating layer provided on the gate electrode; source and drain electrodes provided on the gate insulating layer to be spaced apart from each other; and a transparent active layer provided on the gate insulating layer, on which the source and drain electrodes are provided, to come into contact with the source and drain electrodes.

### TECHNICAL FIELD

The present invention relates to a laminate for manufacturing a flexible transparent thin-film transistor, a flexible transparent thin-film transistor, and a manufacturing method thereof.

### BACKGROUND ART

Transparent thin-film transistors are manufactured on transparent substrates based on transparent semiconductors, conductors, and dielectrics. Oxide semiconductors suitable for these thin-film transistors are semiconductor materials with high mobility values and wide band gaps, and oxides such as indium oxide, gallium oxide, tin oxide, and zinc oxide are mainly used. In particular, the flexible transparent thin-film transistors have advantages in that they are not only applicable to flexible electronic devices but are also easily developed into transparent thin-film transistors with improved elasticity that may replace existing opaque thin-film transistors.

However, in order to form the oxide semiconductor to be used as a transparent active layer, a high-temperature process is required, but when the oxide semiconductor layer is formed directly on a transparent plastic substrate, there is a problem in that the high-temperature process cannot be applied because shrinkage or deformation of the transparent plastic substrate occurs.

To solve the problem that heat treatment in the high-temperature process is impossible as described above, a transfer method has been developed. For example, Korean Patent Application Publication No. 10-2011-0011889 discloses a process of forming a sacrificial layer of germanium or germanium oxide, and then forming an oxide semiconductor layer and removing the sacrificial layer by wet etching, thereby transferring only a semiconductor layer onto a transparent plastic substrate. However, there is a problem in that, because a separate wet etching process is required to remove the sacrificial layer, the process is complicated and the manufacturing time is increased, so that the process efficiency is lowered.

Therefore, there is a need for the development of a flexible transparent thin-film transistor, to which a high-temperature process for forming a transparent active layer including an oxide semiconductor is applicable and which has improved process efficiency due to a relatively simple process of transferring to a transparent plastic substrate, and a method for manufacturing the same.

### DISCLOSURE

### Technical Problem

An object of the present invention is to provide a flexible thin-film transistor having excellent electrical properties while having transparent and flexible properties, and a method for manufacturing the same.

Another object of the present invention is to provide a laminate for manufacturing a flexible thin-film transistor for use in a flexible thin-film transistor and a method for manufacturing the same.

Still another object of the present invention is to provide a laminate for manufacturing a flexible thin-film transistor, to which a high-temperature process for forming an oxide semiconductor is applicable and which has a relatively simple process of transferring to a transparent plastic substrate, a method for manufacturing a flexible transparent thin-film transistor, and a flexible transparent thin-film transistor manufactured thereby.

### Technical Solution

The present invention relates to a laminate for manufacturing a flexible thin-film transistor, including: a carrier substrate; a separation layer provided on the carrier substrate; a protective layer provided to cover the separation layer; a gate electrode provided on the protective layer; a gate insulating layer provided on the gate electrode; a source electrode and drain electrode provided on the gate insulating layer so as to be spaced apart from each other; and a transparent active layer provided on the gate insulating layer having the source electrode and drain electrode provided thereon, which is in contact with the source electrode and the drain electrode.

The present invention also relates to a flexible thin-film transistor including: a flexible substrate; a protective layer provided on the flexible substrate; a gate electrode provided on the protective layer; a gate insulating layer provided on the gate electrode; a source electrode and drain electrode provided on the gate insulating layer so as to be spaced apart from each other; and a transparent active layer provided on the gate insulating layer having the source electrode and drain electrode provided thereon, which is in contact with the source electrode and the drain electrode.

According to one embodiment of the present invention, the carrier substrate may include at least one selected from the group consisting of a wafer, copper (Cu), nickel (Ni), a copper-nickel alloy, and glass.

According to one embodiment of the present invention, the source electrode and the drain electrode may have a taper angle of less than 40° formed between the end on their side in contact with the transparent active layer and the gate insulating layer.

According to one embodiment of the present invention, the gate electrode, the source electrode and the drain electrode may include at least one selected from the group consisting of indium tin oxide (ITO), indium zinc oxide (IZO), zinc oxide (ZnO), indium oxide (In₂O₃), indium gallium oxide (IGO), aluminum zinc oxide (AZO), and indium tin zinc oxide (ITZO).

According to one embodiment of the present invention, the transparent active layer may be provided to cover a portion of each of the source electrode and the drain electrode.

According to one embodiment of the present invention, the transparent active layer may include at least one selected from the group consisting of ZnSnO, CdSnO, GaSnO, TISnO, InGaZnO, CuAlO, SrCuO, LaCuOS, GaN, InGaN, AlGaN, AlGaN, and InGaAlN.

According to one embodiment of the present invention, the flexible thin-film transistor may further include a separation layer between the flexible substrate and the protective layer.

The present invention also relates to a method for manufacturing a flexible thin-film transistor, including steps of: forming a separation layer on a carrier substrate; forming a protective layer on the carrier substrate having the separation layer formed thereon so as to cover the separation layer; forming a gate electrode on the protective layer; forming a gate insulating layer on the gate electrode; forming a source electrode and a drain electrode on the gate insulating layer so as to be spaced apart from each other; forming a passivation layer on the source electrode, the drain electrode, and a transparent active layer; peeling off the carrier substrate by cutting out portions where the carrier substrate and the protective layer are in direct contact; and transferring a laminate from which the carrier substrate has been peeled off to a flexible substrate.

According to one embodiment of the present invention, the step of peeling off the carrier substrate may include peeling off the carrier substrate and the separation layer together.

### Advantageous Effects

When the laminate for manufacturing a flexible thin-film transistor according to the present invention is used, it is possible to transfer a transparent semiconductor element to a flexible substrate without damage after a high-temperature process for forming a transparent active layer, and thus it is possible to provide a flexible thin-film transistor having excellent electrical properties while having transparent and flexible properties.

In addition, according to the laminate for manufacturing a flexible thin-film transistor and the method for manufacturing a flexible thin-film transistor using the same according to the present invention, it is possible to simply peel off the carrier substrate without a separate process such as wet etching. Therefore, it is possible to improve process efficiency by simplifying the process of transferring a transparent semiconductor element to a flexible substrate.

In addition, according to the laminate for manufacturing a flexible thin-film transistor and the flexible thin-film transistor according to the present invention, a transparent active layer may be provided on a gate insulating layer having a source electrode and drain electrode provided thereon such that it is in contact with the source electrode and the drain electrode, so that only the transparent active layer may be selectively etched in the process of forming the transparent active layer, thereby simplifying the overall process and improving process efficiency.

### BRIEF DESCRIPTION OF DRAWINGS

FIG. 1 is a schematic sectional view showing a laminate for manufacturing a flexible thin-film transistor according to one embodiment of the present invention.

FIGS. 2 and 3 are schematic sectional views showing a flexible thin-film transistor according to one embodiment of the present invention.

FIG. 4 is schematic sectional views showing each step of a method for manufacturing a laminate for manufacturing a flexible thin-film transistor according to one embodiment of the present invention.

FIGS. 5, 6 and 7 are schematic sectional views showing each step of a method for manufacturing a flexible thin-film transistor according to one embodiment of the present invention.

FIG. 8 is a scanning electron microscope (SEM) photograph of a section of a flexible thin-film transistor according to one embodiment of the present invention.

FIG. 9 shows an IV transfer curve of a flexible thin-film transistor according to one embodiment of the present invention.

### BEST MODE

The present invention relates to a flexible thin-film transistor, to which a high-temperature process for forming a transparent active layer including an oxide semiconductor is applicable and which has improved process efficiency due to a relatively simple process of transferring to a transparent plastic substrate, a method for manufacturing the same, and a laminate for manufacturing a flexible thin-film transistor, which is used therein.

More specifically, the present invention relates to a laminate for manufacturing a flexible thin-film transistor, including: a carrier substrate; a separation layer provided on the carrier substrate; a protective layer provided to cover the separation layer; a gate electrode provided on the protective layer; a gate insulating layer provided on the gate electrode; a source electrode and drain electrode provided on the gate insulating layer so as to be spaced apart from each other; and a transparent active layer provided on the gate insulating layer having the source electrode and drain electrode provided thereon, which is in contact with the source and electrodes.

The present invention also relates to a flexible thin-film transistor including: a flexible substrate; a protective layer provided on the flexible substrate; a gate electrode provided on the protective layer; a gate insulating layer provided on the gate electrode; a source electrode and drain electrode provided on the gate insulating layer so as to be spaced apart from each other; and a transparent active layer provided on the gate insulating layer having the source electrode and drain electrode provided thereon, which is in contact with the source electrode and the drain electrode.

The present invention also relates to a method for manufacturing a flexible thin-film transistor, including steps of: forming a separation layer on a carrier substrate; forming a protective layer on the carrier substrate having the separation layer formed thereon so as to cover the separation layer; forming a gate electrode on the protective layer; forming a gate insulating layer on the gate electrode; forming a source electrode and a drain electrode on the gate insulating layer so as to be spaced apart from each other; forming a passivation layer on the source electrode, a drain electrode, and a transparent active layer; peeling off the carrier substrate by cutting out portions where the carrier substrate and the protective layer are in direct contact; and transferring a laminate from which the carrier substrate has been peeled off to a flexible substrate.

Hereinafter, embodiments of the present invention will be described in more detail with reference to the accompanying drawings. However, the following drawings attached to the present specification illustrate preferred embodiments of the present invention, and serve to aid in further understanding of the technical idea of the present invention together with the contents of the present invention described above. Therefore, the present invention should not be interpreted as being limited only to matters described in the drawings and is defined only by the scope of the claims.

Terms used in the present specification are for purpose of describing embodiments and are not intended to limit the present disclosure. In the present specification, singular forms also include plural forms unless the context clearly indicates otherwise.

As used herein, terms such as “comprise”, “comprising”, “include”, and “including” are intended to denote the existence of one or more stated components, steps, operations, and/or elements, but do not exclude the probability of existence or addition of one or more other components, steps, operations, and/or elements. Throughout the specification, like reference numerals refer to like components.

Spatially relative terms, such as “above”, “below”, “upper surface”, “lower surface”, “on”, “beneath” , and the like, may be used to easily describe the relationship between one element or component(s) and other element or components(s) as illustrated in the figures. Spatially relative terms should be understood to encompass different orientations of the element in use or operation, in addition to the orientation depicted in the figures. For example, when elements illustrated in the figures are turned over, an element described as being “below” or “beneath” another element may be placed “above” or “on” the other element. Thus, the exemplary term “below” may include both the terms “above” and “below”. The element may also be oriented in a different direction, and thus spatially relative terms may be interpreted according to the orientation.

In the drawings below, a direction parallel to the upper surface of a carrier substrate 110 or a flexible substrate 150 is defined as a “planar direction,” and a direction perpendicular to the upper surface of the carrier substrate 110 or the flexible substrate 150 is defined as a “vertical direction.” For example, the planar direction and the vertical direction may intersect each other perpendicularly.

### Mode for Invention

### <Laminate for Manufacturing Flexible Thin-Film Transistor>

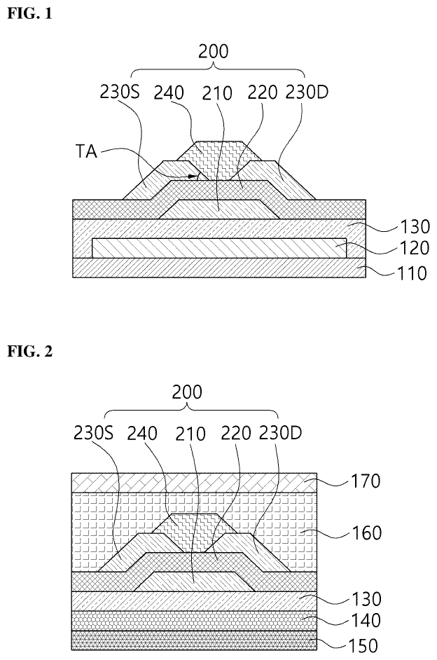

FIG. 1 is a schematic sectional view showing a laminate for manufacturing a flexible thin-film transistor according to one embodiment of the present invention.

Referring to FIG. 1, a laminate for manufacturing a flexible thin-film transistor according to the present invention may include a carrier substrate 110, a separation layer 120 provided on the carrier substrate 110, a protective layer 130 provided to cover the separation layer 120, and a transparent semiconductor element 200 provided on the protective layer 130.

Although the carrier substrate 110 is not particularly limited as long as it is applicable to a high-temperature process, it may include, for example, at least one selected from the group consisting of a wafer, copper (Cu), nickel (Ni), a copper-nickel alloy, and glass.

The separation layer 120 is a polymer organic layer, and may include, for example, at least one material selected from the group consisting of polyimide, polyvinyl alcohol, polyamic acid, polyamide, polyethylene, polystyrene, polynorbornene, phenylmaleimide copolymers, polyazobenzene, polyphenylenephthalamide, polyester, polymethyl methacrylate, polyarylate, melamine-based polymers, cinnamate-based polymers, coumarin-based polymers, phthalimidine-based polymers, chalcone-based polymers, and aromatic acetylene-based polymers.

The peeling force of the separation layer 120 from the carrier substrate may be 1 N/25 mm or less, preferably 0.01 to 1 N/25 mm, more preferably 0.01 to 0.1 N/25 mm. When the peeling force of the separation layer 120 is within the above range, the separation layer and the carrier substrate may remain stably attached to each other during the process of forming the transparent semiconductor element 200, and the separation layer may be separated cleanly without cracking during a subsequent process of peeling the separation layer 120 from the carrier substrate 110.

In addition, the thickness of the separation layer 120 may preferably be 1 to 1,000 nm, more preferably 10 to 500 nm. When the thickness of the separation layer is within the above range, it is preferable because it is possible to prevent a decrease in uniformity after applying the separation layer, thereby maintaining good flexible properties while preventing a local increase in peeling force or tearing.

The protective layer 130 is provided to cover the separation layer 120) and may protect the transparent semiconductor element 200 from damage and breakage during and/or after peeling of the carrier substrate 110.

The protective layer 130 may be formed to completely cover the separation layer 120 on the carrier substrate 110. Accordingly, portions of the protective layer 130 may be formed in direct contact with the carrier substrate 110, and allow the separation layer 120 and the carrier substrate 110 to remain stably adhered during the process until the carrier substrate 110 is peeled off.

The protective layer 130 may include an inorganic dielectric material such as an inorganic oxide or an inorganic nitride, or a polymer-based organic dielectric material. Examples of the inorganic oxide include silicon oxide, alumina, titanium oxide, etc., and examples of the inorganic nitride include silicon nitride, titanium nitride, etc. In terms of realizing all of excellent mechanical strength, transmittance, and flexible properties, the protective layer 130 may include a cyclo-olefin polymer (COP).

Examples of the cyclo-olefin polymer (COP) include, but are not limited to, polynorbornene, polycycloalkene, polydicyclopentadiene, etc.

In addition, the thickness of the protective layer 130 is preferably 1 to 5 μm. When the thickness of the protective layer is within the above range, it is preferable because it may function as a protective layer without deteriorating the flexible properties. If the thickness of the protective layer 130 is more than 5 μm, the flexible properties may deteriorate, and if the thickness is less than 1 μm, there may be a problem in that the protective layer loses the function as a protective layer.

The transparent semiconductor element 200 may include a gate electrode 210, a gate insulating layer 220 provided on the gate electrode, a source electrode 230S and drain electrode 230D provided on the gate insulating layer 220 so as to be spaced apart from each other, and a transparent active layer 240 provided on the gate insulating layer 220 having the source electrode 230S and drain electrode 230D provided thereon, which is in contact with the source electrode and the drain electrode.

The gate electrode 210 is provided on the protective layer 130, and a signal wire (not shown) made of the same material as the gate electrode 210 may be further formed.

The gate insulating layer 220 is provided on the gate electrode 210. The gate insulating layer 220 may be formed of an inorganic or organic dielectric material, and is preferably composed of a transparent material. For example, it may be composed of a silicon oxide layer or a silicon nitride layer, without being limited thereto and may be formed of various materials.

The source electrode 230S and the drain electrode 230D are provided on the gate insulating layer 220 so as to be spaced apart from each other.

The source electrode 230S and the drain electrode 230D may have a taper angle (see TA in FIG. 1) of 40° or less, preferably 2 to 40°, more preferably 5 to 35°, formed between the end on their side in contact with the transparent active layer and the gate insulating layer. If the source electrode 230S and the drain electrode 230D have a taper angle of more than 40° formed between the end on their side in contact with the transparent active layer and the gate insulating layer, a problem may arise in that the step coverage may be reduced after forming the transparent active layer 240 described later, and thus a short circuit occurs, resulting in reduced electrical properties.

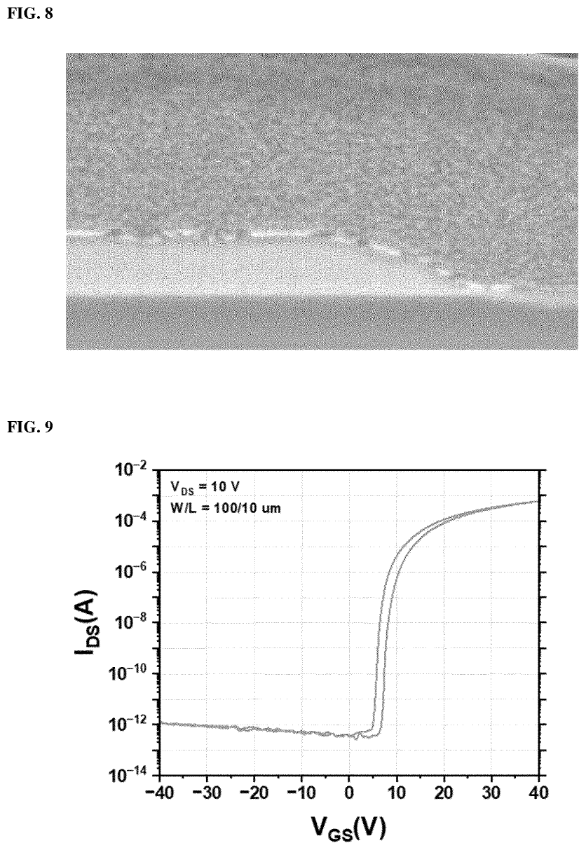

FIGS. 8 and 9 show a scanning electron microscope (SEM) photograph of a section of a flexible thin-film transistor according to one embodiment of the present invention and an IV transfer curve of the flexible thin-film transistor, respectively. Specifically, through FIG. 8 showing a photograph of a section of a flexible thin-film transistor according to an embodiment of the present invention, it can be confirmed that the taper angle formed between one end of the source/drain electrode and the gate insulating layer is 25°, and that the thickness of the thin film is 990 Å (Angstrom).

Referring to FIGS. 8 and 9, it can be confirmed that, when the taper angle formed between one end of the source/drain electrode and the gate insulating layer is 40° or less, the IGZO transparent active layer formed on the ITO source/drain electrode is formed smoothly without short circuit (see FIG. 8), and thus may exhibit very excellent electrical properties (see FIG. 9).

The gate electrode 210, the source electrode 230S, and the drain electrode 230D may include at least one selected from the group consisting of indium tin oxide (ITO), indium zinc oxide (IZO), zinc oxide (ZnO), indium oxide (In₂O₃), indium gallium oxide (IGO), aluminum zinc oxide (AZO), and indium tin zinc oxide (ITZO). In addition, they may preferably include indium tin oxide (ITO) in terms of transparency and selective etching during the process. In particular, when the source electrode 230S and the drain electrode 230D include ITO, there is an advantage in that only the IGZO layer may be selectively etched without damaging the source electrode 230S and the drain electrode 230D after forming the IGZO layer as the transparent active layer described later.

The transparent active layer 240 is provided on the gate insulating layer having the source electrode 230S and the drain electrode 230D so as to be in contact with the source electrode and the drain electrode, and may be provided so as to cover a portion of each of the source electrode 230S and the drain electrode 230D.

The transparent active layer 240 may be formed of a semiconductor including amorphous silicon or crystalline silicon. The transparent active layer 240 may include a channel region and impurity ion-doped source and drain regions inside the channel region. The source and drain regions of the active layer 240 may be in contact with the source electrode 230S and the drain electrode 230D, respectively.

The transparent active layer 240 may include at least one selected from the group consisting of ZnSnO, CdSnO, GaSnO, TISnO, InGaZnO, CuAlO, SrCuO, LaCuOS, GaN, InGaN, AlGaN, AlGaN, and InGaAlN. In particular, it may preferably include InGaZnO (IGZO) in terms of electrical properties and selective etching during the process. IGZO has a low off-current, and thus has low power consumption, and it is applicable to high-resolution products due to its high mobility. In addition, IGZO makes it possible to prevent the deterioration of flexible properties and transmittance by applying a relatively low-temperature process, and has the advantage of reducing investment costs as it is similar to that in existing a-Si process equipment.

### <Flexible Thin-Film Transistor>

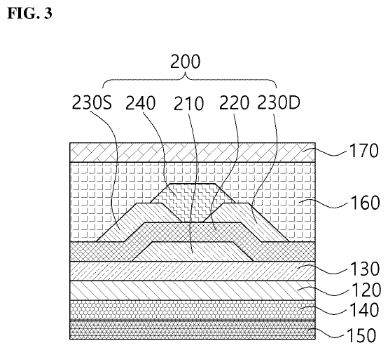

FIG. 2 and FIG. 3 are schematic sectional views showing a flexible thin-film transistor according to one embodiment of the present invention.

Referring to FIG. 2, the flexible thin-film transistor of the present invention may include a flexible substrate 150, a protective layer 130 provided on the flexible substrate 150, and a transparent semiconductor element 200 provided on the protective layer 130, and may further include a passivation layer 160 and a protective film 170 on the transparent semiconductor element 200.

Detailed description of the separation layer 120, protective layer 130, gate electrode 210, gate insulating layer 220, source electrode 230S, drain electrode 230D, and transparent active layer 240 described with reference to FIG. 1 will be omitted.

Although the flexible substrate 150 is not particularly limited as long as it is a transparent material having flexible properties, it may include, for example, at least one selected from the group consisting of a cyclo-olefin polymer (COP), polyethylene terephthalate (PET), polyacrylate (PAR), polyetherimide (PEI), polyethylene naphthalate (PEN), polyphenylene sulfide (PPS), polyallylate, clear polyimide (CPI), polyimide (PI), cellulose acetate propionate (CAP), polyether sulfone (PES), cellulose triacetate (TAC), polycarbonate (PC), a cyclo-olefin copolymer (COC), and polymethyl methacrylate (PMMA). Preferably, it may include at least one selected from the group consisting of polyethylene terephthalate (PET), clear polyimide (CPI), a cyclo-olefin polymer (COP), polyethylene naphthalate (PEN), and polycarbonate (PC). More preferably, it may include at least one selected from the group consisting of polyethylene terephthalate (PET), a cyclo-olefin polymer (COP), polyethylene naphthalate (PEN), and polycarbonate (PC).

In one embodiment of the present invention, an adhesive layer 140 may be provided on the upper surface of the flexible substrate 150. For example, the separation layer 120 or the protective layer 130 may be adhered to the flexible substrate 150 through the adhesive layer 140, thereby preventing the flexible substrate 150 from being peeled off or lifted.

The passivation layer 160 serves to protect the transparent semiconductor element 200 from external damage such as moisture, and it may be formed of the same material as the gate insulating layer 220, and may be formed as a single layer or multiple layers, without being limited thereto.

The protective film 170 serves to protect against physical damage or the like from post-processing and external environments, and may be provided on the passivation layer 160.

The protective film 170 may include at least one selected from the group consisting of polyethylene terephthalate (PET), polyethylene isophthalate (PEI), polyethylene naphthalate (PEN), polybutylene terephthalate (PBT), diacetyl cellulose, triacetyl cellulose (TAC), polycarbonate (PC), polyethylene (PE), polypropylene (PP), polymethyl acrylate (PMA), polymethyl methacrylate (PMMA), polyethyl acrylate (PEA), polyethyl methacrylate (PEMA), and a cyclo-olefin polymer (COP).

### <Method for Manufacturing Flexible Thin-Film Transistor>

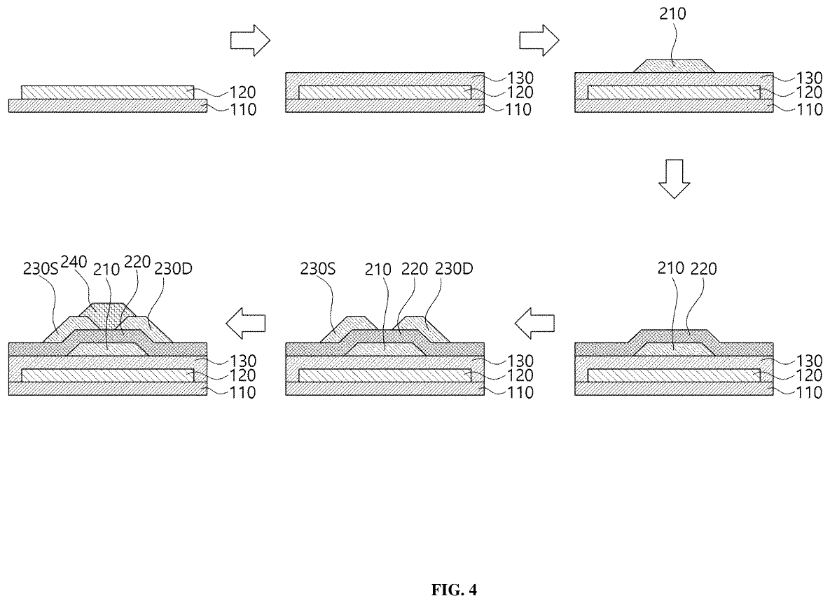

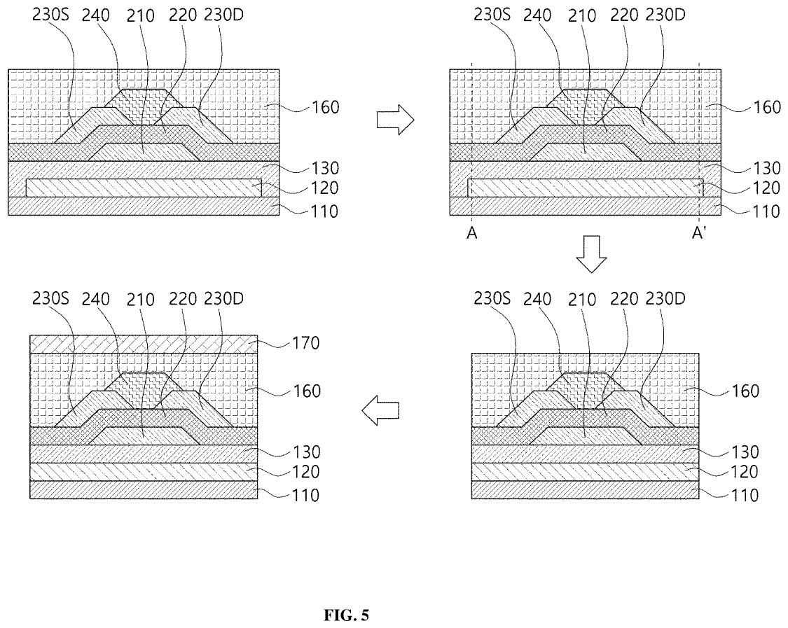

FIG. 4 is schematic sectional views showing each step of a method for manufacturing a laminate for manufacturing a flexible thin-film transistor according to one embodiment of the present invention, and FIGS. 5, 6 and 7 are schematic sectional views showing each step of a method for manufacturing a flexible thin-film transistor according to one embodiment of the present invention.

Detailed description of the carrier substrate 110, separation layer 120, protective layer 130, gate electrode 210, gate insulating layer 220, source electrode 230S, drain electrode 230D, transparent active layer 240, flexible substrate 150, adhesive layer 140, passivation layer 160, and protective film 170 described with reference to FIGS. 1 to 3 will be omitted.

Referring to FIG. 4, a separation layer 120 is first formed on a carrier substrate 110. The separation layer 120 may be formed through a process of applying a composition for forming a separation layer onto a carrier substrate 110, followed by drying, or may be formed by laminating a separately formed separation layer 120 on the carrier substrate 110.

Thereafter, a protective layer 130 is formed on the carrier substrate 110 having the separation layer 120 formed thereon so as to cover the separation layer 120. At this time, the protective layer 130 may be formed to completely cover the separation layer 120. The protective layer 130 may be formed through a process of applying a composition for forming a protective layer onto the carrier substrate 110, followed by drying, without being limited thereto.

Next, a gate electrode 210 is formed on the protective layer 130. The gate electrode 210 is formed in a predetermined pattern, and a signal wire (not shown) made of the same material as the gate electrode 210 may be further formed.

A gate insulating layer 220 is formed on the gate electrode 210, and a source electrode 230S and a drain electrode 230D are formed on the gate insulating layer 220 so as to be spaced apart from each other. The source electrode 230S and the drain electrode 230D are formed in a predetermined pattern, and may be formed of the same material as the gate electrode 210.

The source electrode 230S and the drain electrode 230D may be formed so that the taper angle (see TA in FIG. 1) formed between the end on their side that will be in contact with a transparent active layer 240 in a subsequent process and the gate insulating layer is 40° or less, preferably 2 to 40°, more preferably 5 to 35°. If the source electrode 230S and the drain electrode 230D have a taper angle of more than 40° formed between the end on their side that will be in contact with the transparent active layer 240 and the gate insulating layer, a problem may arise in that the step coverage may be reduced after subsequent formation of the transparent active layer 240, and thus a short circuit occurs, resulting in reduced electrical properties.

Finally, the transparent active layer 240 is formed on the gate insulating layer 220 having the source electrode 230S and drain electrode 230D formed thereon so as to be in contact with the source electrode 230S and the drain electrode 230D. At this time, a predetermined pattern may be formed by a process of selectively etching only the transparent active layer 240 so as not to cause damage to the underlying source electrode 230S and drain electrode 230D.

In contrast, in the case of a structure in which the transparent active layer is formed first and then the source electrode and the drain electrode are formed, an etchant composition that etches the source electrode and the drain electrode also etches the underlying transparent active layer. Therefore, in order to prevent damage to the underlying transparent active layer, a separate etch stop layer (ESL) is introduced or an additional process such as lift-off is required, which may lower the overall process efficiency.

Each layer included in the transparent semiconductor element 200 may be formed at a temperature lower than 400° C., preferably 300° C. or lower, more preferably 200° C. or lower. If each layer included in the transparent semiconductor element 200 is formed at a temperature higher than 400° C., damage may be caused to the separation layer 120 and protective layer 130 laminated as lower layers, and thus it is necessary to form the separation layer 120 and the protective layer 130 thicker to maintain their function. If the thicknesses of the separation layer 120 and the protective layer 130 increase, there is a problem in that the flexible properties and transmittance of the flexible thin-film transistor may be reduced. That is, when each layer included in the transparent semiconductor element 200 is formed at a temperature lower than 400° C., it is preferable because the reduction in the flexible properties and transmittance of the flexible thin-film transistor may be prevented.

In addition, a passivation layer 160 may further be formed to protect the source electrode 230S, the drain electrode 230D, and the transparent active layer 240.

FIG. 5 is schematic sectional views showing some steps of manufacturing a flexible thin-film transistor from a laminate for manufacturing a flexible thin-film transistor according to one embodiment of the present invention.

Referring to FIG. 5, the side portions where the carrier substrate 110 and the protective layer 130 are in direct contact are cut from the laminate for manufacturing a flexible thin-film transistor according to the present invention. That is, both side portions of the separation layer 120 are cut in a direction perpendicular to the upper surface of the carrier substrate 110 (see lines A and A′ in FIG. 5). Accordingly, the portions where the carrier substrate 110 and the protective layer 130 are in direct contact are removed from the laminate. At this time, the cutting method is not particularly limited, and for example, a cutting process may be performed using a laser. By the cutting process, in addition to the carrier substrate 110, the separation layer 120, and the protective layer 130, portions of other layers may also be cut within a range in which the function of the transparent semiconductor element 200 is maintained.

Thereafter, a protective film 170 may be attached onto the passivation layer 160 of the laminate that has undergone the cutting process.

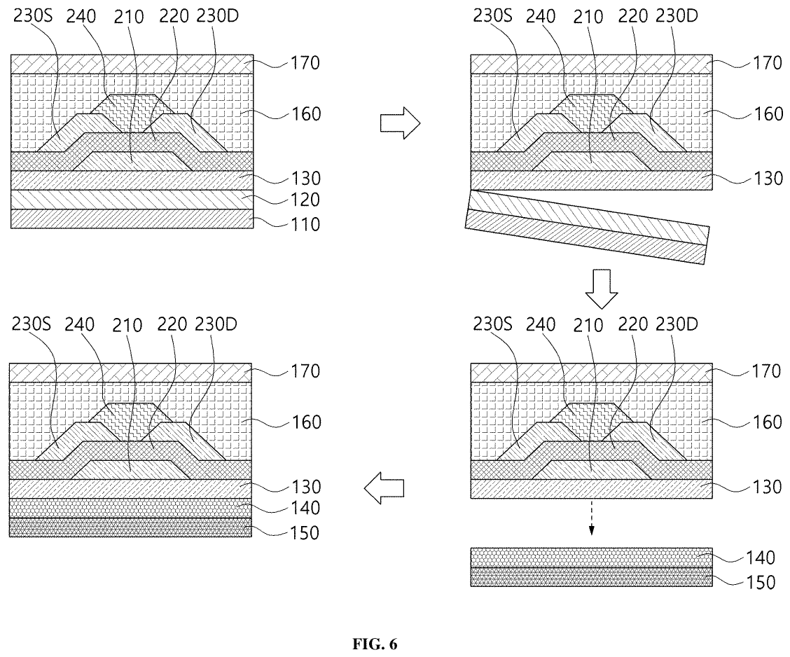

FIG. 6 is a schematic sectional view showing each step of manufacturing a flexible thin-film transistor according to one embodiment of the present invention from a laminate from which the portions where the carrier substrate 110 and the protective layer 130 are in direct contact with each other have been removed.

Referring to FIG. 6, first, the carrier substrate 110 and the separation layer 120 are peeled off from the laminate from which the portions where the carrier substrate 110 and the protective layer 130 are in direct contact have been removed.

As described above, the carrier substrate 110 and the separation layer 120 are stably adhered through the portions where the carrier substrate 110 and the protective layer 130 are in direct contact. Therefore, the carrier substrate 110 and the separation layer 120 may be easily peeled off without damaging the transparent semiconductor element 200 by simply applying a physical force to the laminate from which the portions have been removed, and a separate chemical treatment process or a decomposition process using a laser is not required.

Thereafter, the laminate from which the carrier substrate 110 and the separation layer 120 have been peeled off is transferred to a flexible substrate 150 having an adhesive layer 140 formed on one surface, thereby manufacturing a flexible thin-film transistor. At this time, it is preferable that the adhesive layer 140 be formed to have a small thickness of 1 μm or less.

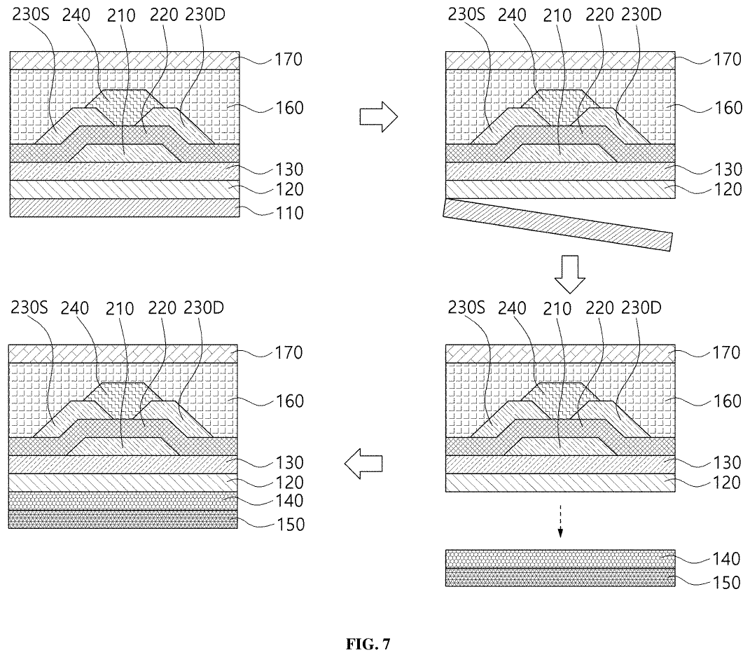

FIG. 7 is a schematic sectional view showing each step of manufacturing a flexible thin-film transistor according to another embodiment of the present invention from the laminate from which the portions where the carrier substrate 110 and the protective layer 130 are in direct contact with each other have been removed.

Referring to FIG. 7, first, the carrier substrate 110 is peeled off from the laminate from which the portions where the carrier substrate 110 and the protective layer 130 are in direct contact have been removed. That is, unlike in FIG. 6 described above, the separation layer 120 is not peeled off together with the carrier substrate 110, but remains adhered to the protective layer 130.

Thereafter, the laminate from which the carrier substrate 110 has been peeled off is transferred to a flexible substrate 150 having an adhesive layer 140 formed on one surface, thereby manufacturing a flexible thin-film transistor.

According to one embodiment of the present invention, the peeling force between the separation layer 120 and the protective layer 130 may be appropriately controlled by controlling the components included in the separation layer 120 and/or the protective layer 130. When the peeling force of the protective layer 130 from the separation layer 120 is lower than the peeling force of the carrier substrate 110 from the separation layer 120, the separation layer 120 and the carrier substrate 110 may be peeled together from the protective layer 130 using the protective layer 130 and the separation layer 120 as an interface (see FIG. 6). In addition, when the peeling force of the protective layer 130 from the separation layer 120 is greater than the peeling force of the carrier substrate 110 from the separation layer 120, the carrier substrate 110 may be peeled from the separation layer 120 using the separation layer 120 and the carrier substrate 110 as an interface (see FIG. 7).

### INDUSTRIAL APPLICABILITY

When the laminate for manufacturing a flexible thin-film transistor according to the present invention is used, it is possible to transfer a transparent semiconductor element to a flexible substrate without damage after a high-temperature process for forming a transparent active layer, and thus it is possible to provide a flexible thin-film transistor having excellent electrical properties while having transparent and flexible properties.

1. A laminate for manufacturing a flexible thin-film transistor, comprising:
a carrier substrate;
a separation layer provided on the carrier substrate;
a protective layer provided to cover the separation layer;
a gate electrode provided on the protective layer;
a gate insulating layer provided on the gate electrode;
a source electrode and drain electrode provided on the gate insulating layer so as to be spaced apart from each other; and
a transparent active layer provided on the gate insulating layer having the source electrode and drain electrode provided thereon, which is in contact with the source electrode and the drain electrode.

2. The laminate of claim 1, wherein the carrier substrate comprises at least one selected from the group consisting of a wafer, copper (Cu), nickel (Ni), a copper-nickel alloy, and glass.

3. The laminate of claim 1, wherein the source electrode and the drain electrode have a taper angle of 40° or less formed between the end on their side in contact with the transparent active layer and the gate insulating layer.

4. The laminate of claim 1, wherein the gate electrode, the source electrode, and the drain electrode comprise at least one selected from the group consisting of indium tin oxide (ITO), indium zinc oxide (IZO), zinc oxide (ZnO), indium oxide (In₂O₃), indium gallium oxide (IGO), aluminum zinc oxide (AZO), and indium tin zinc oxide (ITZO).

5. The laminate of claim 1, wherein the transparent active layer is provided to cover a portion of each of the source electrode and the drain electrode.

6. The laminate of claim 1, wherein the transparent active layer comprises at least one selected from the group consisting of ZnSnO, CdSnO, GaSnO, TISnO, InGaZnO, CuAlO, SrCuO, LaCuOS, GaN, InGaN, AlGaN, and InGaAlN.

7. A flexible thin-film transistor comprising:
a flexible substrate;
a protective layer provided on the flexible substrate;
a gate electrode provided on the protective layer;
a gate insulating layer provided on the gate electrode;
a source electrode and drain electrode provided on the gate insulating layer so as to be spaced apart from each other; and
a transparent active layer provided on the gate insulating layer having the source electrode and drain electrode provided thereon, which is in contact with the source electrode and the drain electrode.

8. The flexible thin-film transistor of claim 7, wherein the source electrode and the drain electrode have a taper angle of 40° or less formed between the end on their side in contact with the transparent active layer and the gate insulating layer.

9. The flexible thin-film transistor of claim 7, wherein the gate electrode, the source electrode, and the drain electrode comprise at least one selected from the group consisting of indium tin oxide (ITO), indium zinc oxide (IZO), zinc oxide (ZnO), indium oxide (In₂O₃), indium gallium oxide (IGO), aluminum zinc oxide (AZO), and indium tin zinc oxide (ITZO).

10. The flexible thin-film transistor of claim 7, wherein the transparent active layer is provided to cover a portion of each of the source electrode and the drain electrode.

11. The flexible thin-film transistor of claim 7, wherein the transparent active layer comprises at least one selected from the group consisting of ZnSnO, CdSnO, GaSnO, TISnO, InGaZnO, CuAlO, SrCuO, LaCuOS, GaN, InGaN, AlGaN, and InGaAlN.

12. The flexible thin-film transistor of claim 7, further comprising a separation layer between the flexible substrate and the protective layer.

13. A method for manufacturing a flexible thin-film transistor, comprising steps of:
forming a separation layer on a carrier substrate;
forming a protective layer on the carrier substrate having the separation layer formed thereon so as to cover the separation layer;
forming a gate electrode on the protective layer;
forming a gate insulating layer on the gate electrode;
forming a source electrode and a drain electrode on the gate insulating layer so as to be spaced apart from each other;
forming, on the gate insulating layer having the source electrode and the drain electrode formed thereon, a transparent active layer provided so as to be in contact with the source electrode and the drain electrode;
forming a passivation layer on the source electrode, the drain electrode, and the transparent active layer;
peeling off the carrier substrate by cutting out portions where the carrier substrate and the protective layer are in direct contact; and
transferring a laminate from which the carrier substrate has been peeled off to a flexible substrate.

14. The method of claim 13, wherein the step of peeling off the carrier substrate comprises peeling off the carrier substrate and the separation layer together.
